(19) United States
(12) Patent Application Publication
(10) Pub. No.: US 2009/0042397 A1
(43) Pub. Date: Feb. 12, 2009

(54) COPPER RE-DEPOSITION PREVENTING METHOD, SEMICONDUCTOR DEVICE MANUFACTURING METHOD, AND SUBSTRATE PROCESSING APPARATUS

(75) Inventor: Hidenori MIYOSHI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/178,158

(22) Filed: Jul. 23, 2008

(30) Foreign Application Priority Data
Aug. 9, 2007 (JP) 2007-207911

(51) Int. Cl. H01L 21/306

(52) U.S. Cl. 438/706; 156/345.24; 257/E21.226

(57) ABSTRACT

A copper re-deposition preventing method includes placing inside a chamber a target substrate with a film including a copper-containing substance and formed thereon, and performing removal of the copper-containing substance from the target substrate placed inside the chamber, by dry cleaning using an organic compound. Then, the method includes unloading from the chamber the target substrate processed by the removal of the copper-containing substance, and depositing a coating film inside the chamber, in which the target substrate processed by the removal of the copper-containing substance is no longer present, thereby covering copper-containing scattered particles left inside the chamber.

### BACKGROUND OF THE INVENTION

1. Field of the Invention

The present invention relates to a copper re-deposition preventing method, a semiconductor device manufacturing method, and a substrate processing apparatus, and particularly to a method for preventing copper from being re-deposited on a semiconductor wafer including a copper-containing electric connector member, along with a semiconductor device manufacturing method utilizing the preventing method, a substrate processing apparatus usable for performing the preventing method, and a storage medium for controlling the substrate processing apparatus.

2. Description of the Related Art

In recent years, semiconductor devices employ multi-layered structures including interconnection lines stacked one above the other, so as to increase the operation speed and to decrease the size. In order to increase the operation speed, it is necessary to decrease the resistivity of interconnection lines serving as electric connector members and the electric capacitance between interconnection lines. For this reason, copper (Cu), which is low in resistivity, is widely used for interconnection lines, while a low dielectric constant insulation film (Low-k film) is widely used for interlayer insulation films between Cu interconnection lines to decrease the capacitance between the Cu interconnection lines.

Cu is apt to be oxidized, and so copper oxide can be easily formed on the Cu surface. Since the copper oxide thus formed increases the resistivity of Cu, a pre-process or the like is performed to remove the copper oxide by organic acid dry cleaning. Examples of organic acid dry cleaning are disclosed in Non-Patent Document 1 (Kenji Ishikawa and three others, “Dry cleaning of copper surface: a study of dimer-concentration for formic acid vapor”, 67th Academic Lecture Meeting of Japan Society of Applied Physics (in the fall of 2006, Ritsumeikan University), 31a-ZN-7, p 754), and Non-Patent Document 2(Masakazu Hayashi and three others, “Study of Dry Cleaning for Cu Surface: Formation of Volatile Compounds by Organic Acid Vapor Exposure”, 67th Academic Lecture Meeting of Japan Society of Applied Physics (in the fall of 2006, Ritsumeikan University), 31a-ZN-8, p 754).

However, when copper oxide is etched by organic acid dry cleaning, copper particles are scattered inside the chamber. The scattered copper particles may be deposited on the inner wall of the chamber and the susceptor and thereby remain inside the chamber. If a process is performed on a semiconductor wafer inside the chamber with copper deposits remaining therein, copper contamination may be caused on semiconductor devices. For example, it is assumed that copper deposits on the susceptor are peeled off and are re-deposited on a low dielectric constant insulation film used as an interlayer insulation film. In this case, since copper can be diffused into the low dielectric constant insulation film, as is commonly known, interconnection line characteristics may be deteriorated such that the low dielectric constant insulation film causes insulation breakdown, for example.

### BRIEF SUMMARY OF THE INVENTION

An object of the present invention is to provide a copper re-deposition preventing method, which can prevent copper from being re-deposited on a target substrate, and a semiconductor device manufacturing method utilizing this preventing method, which can perform organic acid dry cleaning without deteriorating interconnection line characteristics. Another object of the present invention is to provide a substrate processing apparatus usable for performing the preventing method, and a storage medium for controlling the substrate processing apparatus.

According to a first aspect of the present invention, there is provided a copper re-deposition preventing method comprising: placing inside a chamber a target substrate with a film including a copper-containing substance and formed thereon; performing removal of the copper-containing substance from the target substrate placed inside the chamber, by dry cleaning using an organic compound; unloading from the chamber the target substrate processed by the removal of the copper-containing substance; and depositing a coating film inside the chamber, in which the target substrate processed by the removal of the copper-containing substance is no longer present, thereby covering copper-containing scattered particles left inside the chamber.

In the first aspect, the copper-containing substance may be copper oxide. The organic compound may be selected from the group consisting of an alcohol, an aldehyde, a carboxylic acid, a carboxylic anhydride, an ester, and a ketone. The coating film may be made of a material selected from the group consisting of metal materials, Ta, Ti, W, Mn, Ru, Zn, and Al, oxide of these metal materials, nitride of these metal materials, carbide of these metal materials, and silicide of these metal materials, and SiO, SiN, SiOC, SiC, SiCN, and SiOCN. The method may further comprise cleaning an interior of the chamber to remove layers each comprising the coating film deposited inside the chamber, after repeating said depositing a coating film a predetermined number of times.

According to a second aspect of the present invention, there is provided a semiconductor device manufacturing method comprising: placing inside a chamber a first semiconductor substrate with a film including a copper-containing substance and formed thereon; performing removal of the copper-containing substance from the first semiconductor substrate placed inside the chamber, by dry cleaning using an organic compound; unloading from the chamber the first semiconductor substrate processed by the removal of the copper-containing substance; depositing a first coating film inside the chamber, in which the first semiconductor substrate processed by the removal of the copper-containing substance is no longer present, thereby covering copper-containing scattered particles left inside the chamber; placing, inside a chamber with the first coating film deposited therein, a second semiconductor substrate with a film including a copper-containing substance and formed thereon; performing removal of the copper-containing substance from the second semiconductor substrate placed inside the chamber with the first coating film deposited therein, by the dry cleaning using an organic compound; unloading, from the chamber with the first coating film deposited therein, the second semiconductor substrate processed by the removal of the copper-containing substance; and depositing a second coating film inside the chamber with the first coating film deposited therein, in which the second semiconductor substrate processed by the removal of the copper-containing substance is no longer present, thereby covering copper-containing scattered particles left inside the chamber. In the second aspect, the dry cleaning using an organic compound, said depositing a first coating film, and said depositing a second coating film may be preset to use the same process temperature.

According to a third aspect of the present invention, there is provided a substrate processing apparatus comprising: a chamber; an organic compound-containing gas supply mechanism configured to supply an organic compound-containing gas into the chamber; a film formation gas supply mechanism configured to supply a film formation gas for forming a coating film into the chamber; and a process controller configured to control an operation of the apparatus, wherein the process controller is preset to execute supplying the organic compound-containing gas into the chamber, in which a target substrate with a film including a copper-containing substance and formed thereon is placed, thereby performing removal of the copper-containing substance from the target substrate, by dry cleaning using the organic compound, and, subsequently to unloading from the chamber the target substrate processed by the removal of the copper-containing substance, supplying the film formation gas into the chamber, in which the target substrate processed by the removal of the copper-containing substance is no longer present, thereby depositing a coating film inside the chamber and covering copper-containing scattered particles left inside the chamber. In the third aspect, the process controller may be preset to execute cleaning an interior of the chamber to remove layers each comprising the coating film deposited inside the chamber, after repeating said depositing a coating film a predetermined number of times.

According to a fourth aspect of the present invention, there is provided a storage medium that stores a program for execution on a computer for controlling a substrate processing apparatus, wherein the program, when executed, causes the computer to control the substrate processing apparatus to conduct the copper re-deposition preventing method according to the first aspect.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a flow chart showing the basic flow of a copper re-deposition preventing method according to an embodiment of the present invention;

FIG. 2 is a sectional view showing a substrate processing apparatus usable for performing the copper re-deposition preventing method according to an embodiment of the present invention;

FIG. 3 is a sectional view showing the substrate processing apparatus in a state corresponding to a main process step of a semiconductor device manufacturing method that utilizes a copper re-deposition preventing method according to an embodiment of the present invention;

FIG. 4 is a sectional view showing the substrate processing apparatus in a state corresponding to a main process step of the semiconductor device manufacturing method;

FIG. 5 is a sectional view showing the substrate processing apparatus in a state corresponding to a main process step of the semiconductor device manufacturing method;

FIG. 6 is a sectional view showing the substrate processing apparatus in a state corresponding to a main process step of the semiconductor device manufacturing method;

FIG. 7 is a sectional view showing a semiconductor device in a state that appears during a manufacturing process;

FIG. 8 is a sectional view showing the semiconductor device in a state that appears during the manufacturing process;

FIG. 9 is a sectional view showing the semiconductor device in a state that appears during the manufacturing process;

FIG. 10 is a sectional view showing the semiconductor device in a state that appears during the manufacturing process;

FIG. 11 is a flow chart showing a copper re-deposition preventing method according to an alternative embodiment of the present invention;

FIG. 12 is a sectional view showing a substrate processing apparatus usable for performing the copper re-deposition preventing method according to an alternative embodiment; and

FIG. 13 is a sectional view showing the substrate processing apparatus in a state that appears during a cleaning process.

### DETAILED DESCRIPTION OF THE INVENTION

Embodiments of the present invention will now be described with reference to the accompanying drawings. In all the drawings, the constituent elements having substantially the same function and arrangement are denoted by the same reference numerals.

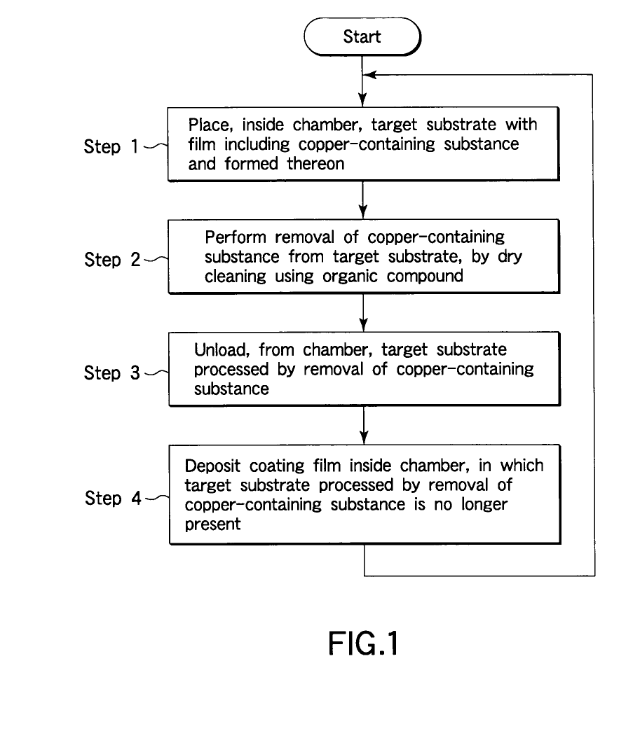

FIG. 1 is a flow chart showing the basic flow of a copper re-deposition preventing method according to an embodiment of the present invention.

As shown in FIG. 1, a copper re-deposition preventing method according to this embodiment is arranged to repeat the following Step 1 to Step 4. Specifically, at first, a target substrate with a film including a copper-containing substance and formed thereon is placed inside a chamber (Step 1). Then, removal of the copper-containing substance is performed on the target substrate placed inside the chamber by dry cleaning using an organic compound (Step 2). Then, the target substrate processed by the removal of the copper-containing substance is unloaded from the chamber (Step 3). Then, a coating film is deposited inside the chamber, in which the target substrate processed by the removal of the copper-containing substance is no longer present, to cover copper-containing scattered particles left inside the chamber (Step 4).

For example, the copper-containing substance is copper oxide.

An example of the dry cleaning using an organic compound is dry cleaning using a reducing organic compound. The reducing organic compound may be exemplified by an alcohol, an aldehyde, a carboxylic acid, a carboxylic anhydride, an ester, and a ketone.

According to this copper re-deposition preventing method, a copper-containing substance is removed by dry cleaning using an organic compound. At this time, the copper-containing substance is scattered inside the chamber and undesirably deposited on members inside the chamber, such as the inner wall of the chamber and the susceptor. Then, a coating film is formed inside the chamber to cover copper-containing scattered particles, as shown in Step 4. Since the coating film is formed to cover copper-containing scattered particles deposited inside the chamber, the scattered particles are sealed below the coating film. Where the copper-containing scattered particles are sealed below the coating film, the scattered particles deposited inside the chamber can be hardly peeled off. Consequently, copper re-deposition is prevented from occurring on a new target substrate placed inside the chamber, and thus copper contamination can be hardly caused on the target substrate. For example, where the target substrate is a semiconductor wafer, since copper re-deposition on a low dielectric constant insulation film used as an interlayer insulation film is suppressed, it is possible to prevent deteriorations in interconnection line characteristics, such as insulation breakdown of the low dielectric constant insulation film.

An example of the coating film is a film that cannot be etched by dry cleaning using an organic compound. However, in place of such a film, the coating film may be formed of a film that can be etched by organic acid dry cleaning. For example, a film that can be etched by organic acid dry cleaning may be used along with at least one of such preset conditions that the film thickness thereof is sufficiently large and that the etching rate thereof is sufficiently low. In other words, even in the latter case, copper-containing scattered particles are reliably covered and are not exposed thereafter, and so the film can be used without a hitch.

As described above, in the copper re-deposition preventing method according to this embodiment, the coating film is used to seal copper-containing scattered particles deposited inside the chamber, so that copper re-deposition on a target substrate is prevented.

Next, a detailed explanation will be given of this embodiment of the present invention, with reference to examples of a substrate processing apparatus and semiconductor device manufacturing method.

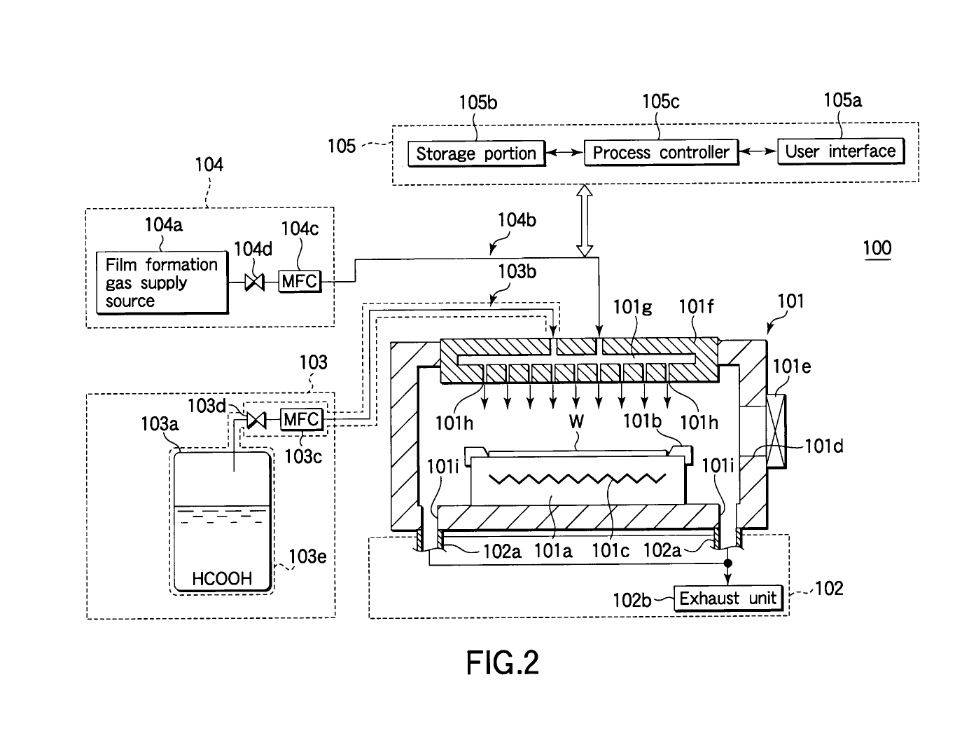

FIG. 2 is a sectional view showing a substrate processing apparatus usable for performing the copper re-deposition preventing method according to an embodiment of the present invention. This apparatus is an organic acid dry cleaning apparatus configured to perform organic acid dry cleaning as an example of dry cleaning using an organic compound.

As shown in FIG. 2, the organic acid dry cleaning apparatus 100 includes a chamber 101 configured to accommodate a target substrate, such as a semiconductor substrate W as in this embodiment. A pressure-decreasing mechanism 102 is disposed to decrease the pressure inside the chamber 101 to a decreased pressure, such as 0.13 Pa or more and 1,333 Pa or less (a pressure within this range is called a vacuum pressure in this specification). An organic acid gas supply mechanism 103 is connected to the chamber 101 to supply an organic acid gas into the chamber 101. Further, a film formation gas supply mechanism 104 is connected to the chamber 101 to supply a film formation gas into the chamber 101. A control mechanism 105 is disposed to control a process on the target substrate.

The chamber 101 has an essentially cylindrical or box-like shape and is opened at the top. The chamber 101 is provided with a susceptor 101a disposed on the bottom to place a semiconductor substrate W thereon. The susceptor 101a is provided with a guide ring 101b on the edge of the substrate mount face. The guide ring 101b is configured to guide the semiconductor wafer W to a predetermined position on the substrate mount face. The susceptor 101a has a heating mechanism or heater 101c embedded therein for heating the semiconductor substrate W. The chamber 101 has a transfer port 101d formed in the sidewall for transferring the semiconductor substrate W therethrough, and the transfer port 101d is provided with a gate valve 101e for opening/closing it.

The top opening of the chamber 101 is closed by a showerhead 101f set to face the susceptor 101a. The showerhead 101f has a diffusion space 101g formed therein to diffuse the organic acid gas from the organic acid gas supply mechanism 103 and the film formation gas from the film formation gas supply mechanism 104. The showerhead 101f further has a plurality of delivery holes 101h formed in the counter surface facing the susceptor 101a. The delivery holes 101h communicate with the diffusion space 101g, so that the organic acid gas or film formation gas supplied into the diffusion space 101g is delivered through the delivery holes 101h into the chamber 101. Exhaust ports 101i are formed at the bottom of the chamber 101.

The pressure-decreasing mechanism 102 includes exhaust lines 102a connected to the exhaust ports 101i and an exhaust unit 102b connected to the exhaust lines 102a. The exhaust unit 102b is configured to forcibly exhaust gas from inside the chamber 101 through the exhaust lines 102a, so that the pressure inside the chamber 101 is decreased to, e.g., a vacuum pressure.

The organic acid gas supply mechanism 103 includes an organic acid gas supply unit 103a, and a supply line 103b for supplying the vaporized organic acid gas into the diffusion space 101g. The supply line 103b is provided with a mass-flow controller 103c (which will be referred to as MFC) and a valve 103d, wherein the MFC 103c is used as a flow rate adjusting mechanism for adjusting the flow rate of the organic acid gas flowing therethrough. In this embodiment, the organic acid used as a gas source for the organic acid gas is formic acid (HCOOH). The formic acid is stored in the organic acid gas supply unit 103a. The organic acid gas supply mechanism 103 includes a heater 103e for heating the supply unit 103a, supply line 103b, MFC 103c, and valve 103d. The organic acid, i.e., formic acid in this embodiment, is heated by the heater 103e to a predetermined temperature and thereby vaporized.

Further, although not shown in FIG. 2, the organic acid gas supply mechanism 103 may be provided with a dilution gas supply mechanism for supplying a dilution gas for diluting the organic acid gas. The dilution gas is exemplified by nitrogen (N₂).

The film formation gas supply mechanism 104 includes a film formation gas supply source 104a, and a supply line 104b for supplying the film formation gas into the diffusion space 101g. The supply line 104b is provided with an MFC 104c and a valve 104d, wherein the MFC 104c is used as a flow rate adjusting mechanism for adjusting the flow rate of the film formation gas flowing therethrough.

The control mechanism 105 includes a user interface 105a, a storage portion 105b, and a process controller 105c. The user interface 105a includes an input device, such as a keyboard, and an indicating device, such as a display, wherein the input device is used for an operator to input commands for operating the organic acid dry cleaning apparatus 100, and the indicating device is used for showing visualized images of the operational status of the apparatus 100 to an operator. The storage portion 105b stores programs (process recipes) for performing processes on target substrates, such as those of Step 1 to Step 4 shown in FIG. 1, and for adjusting the substrate temperature in accordance with process conditions. The process controller 105c controls the organic acid dry cleaning apparatus 100 in accordance with each process recipe. In this embodiment, the recipes are stored in a storage medium included in the storage portion 105b. The storage medium may be formed of a medium of the stationary type, such as a hard disk or semiconductor memory, or a medium of the portable type, such as a CD-ROM, DVD, or flash memory. Alternatively, the recipes may be used online while they are transmitted from another apparatus through, e.g., a dedicated line, as needed.

Next, an explanation will be given of a semiconductor device manufacturing method performed in the organic acid dry cleaning apparatus 100 shown in FIG. 2.

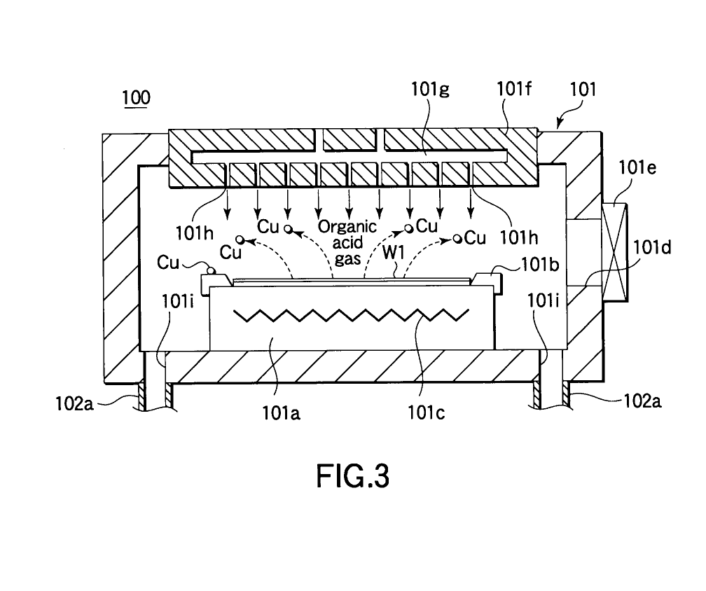

FIGS. 3 to 6 are sectional views showing the substrate processing apparatus in respective states corresponding to main process steps of a semiconductor device manufacturing method that utilizes a copper re-deposition preventing method according to an embodiment of the present invention.

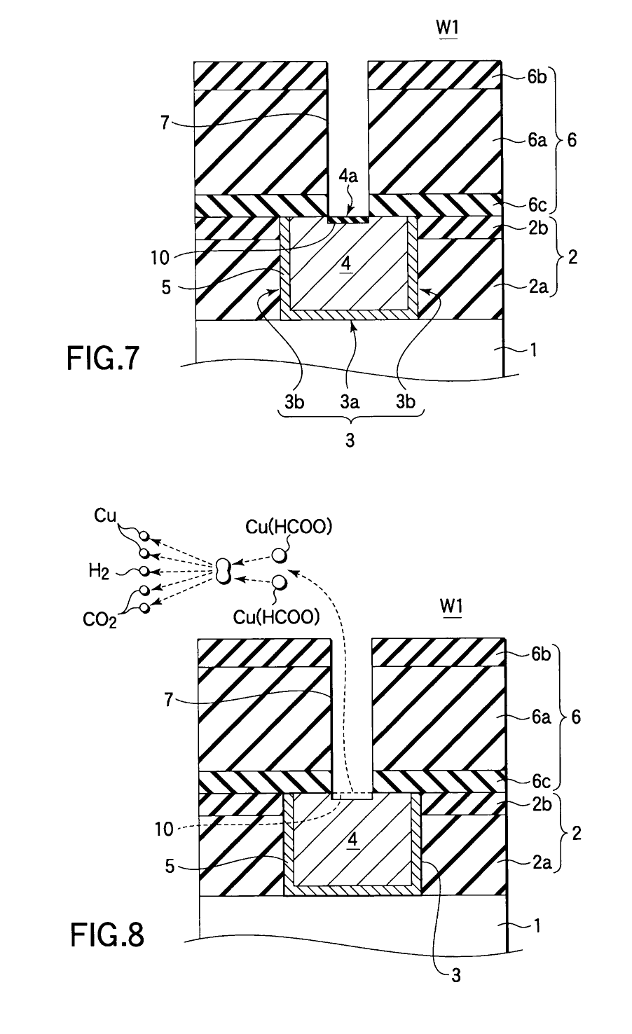

FIGS. 7 to 10 are sectional views showing a semiconductor device in respective states that appear during a manufacturing process.

At first, as shown in FIG. 3, the gate valve 101e is opened, and a first semiconductor wafer W1 is loaded into the chamber 101 and placed on the substrate mount face of the susceptor 101a. The first semiconductor wafer W1 includes copper oxide 10 formed on the surface. FIG. 7 is a sectional view showing a state of a semiconductor device on the semiconductor wafer W1 in a manufacturing process.

As shown in FIG. 7, a first interlayer insulation film 2 is formed on a semiconductor substrate 1 including interlayer insulation films and so forth. The first interlayer insulation film 2 has a groove 3 formed therein, and an interconnection line 4 is formed in the groove 3. This interconnection line 4 is formed from a conductive film made of copper (Cu) and laminated on a barrier layer 5 formed of a conductive layer, which may be made of a metal or the like. Accordingly, in this embodiment, the interconnection line 4 is a copper interconnection line (which will be referred to as a copper interconnection line 4). The barrier layer 5 covers the bottom 3a and side surface 3b of the groove and surrounds the copper interconnection line 4. The barrier layer 5 serves to prevent copper diffusion.

In this embodiment, the first interlayer insulation film 2 comprises a low dielectric constant insulation film 2a having a dielectric constant lower than those of inorganic silicon oxide films. Further, a hard mask layer 2b made of a material different from the low dielectric constant insulation film 2a is formed on the upper surface of the low dielectric constant insulation film 2a.

On top of the first interlayer insulation film 2, a second interlayer insulation film 6 is formed. In this embodiment, the second interlayer insulation film 6 comprises a low dielectric constant insulation film 6a having a dielectric constant lower than those of inorganic silicon oxide films, as in the first interlayer insulation film 2. A hard mask layer 6b made of a material different from the low dielectric constant insulation film 6a is formed on the upper surface of the low dielectric constant insulation film 6a. Further, an etching stopper layer 6c made of a material different from the low dielectric constant insulation film 6a is formed on the lower surface of the low dielectric constant insulation film 6a.

The second interlayer insulation film 6 has a groove 7 formed therein and reaching the upper surface 4a of the copper interconnection line 4, for embedding an internal electric connector member. When this groove 7 is formed, the upper surface 4a of the copper interconnection line 4 comes into contact with air, and copper oxide 10 is thereby generated on the upper surface 4a. In order to remove the copper oxide 10, as shown in FIG. 3, an organic acid gas, i.e., formic acid in this embodiment, is supplied into the chamber 101. Where the organic acid gas is formic acid, the copper oxide 10 is etched in accordance with the following reaction formula (1),

2Cu₂O+2HCOOH→2Cu(HCOO)+H₂O (1),

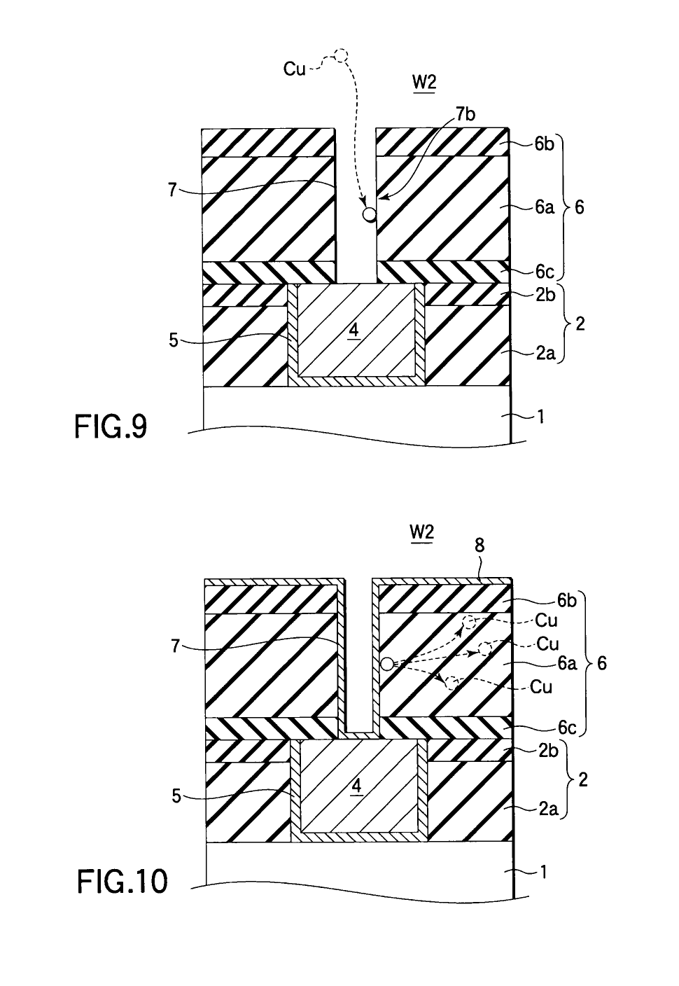

In the reaction formula (1), Cu(HCOO) is volatile. Accordingly, as shown in FIG. 9, the copper oxide (Cu₂O) 10 is etched from the copper interconnection line 4.

However, along with the reaction expressed by the reaction formula (1), a reaction expressed by the following reaction formula (2) also occurs.

2Cu(HCOO)→2Cu+H₂+2CO₂ (2)

Accordingly, as shown in FIG. 8, when two molecules of Cu(HCOO) volatilized and scattered into gas react with each other, two copper atoms Cu, one hydrogen molecule H₂, and two carbon dioxide molecules CO₂ are generated. Consequently, as shown in FIG. 3, copper Cu is scattered inside the chamber 101, and part of the copper Cu which is not exhausted is deposited inside the chamber 101. FIG. 3 shows an example where copper Cu is deposited on the guide ring 101b.

If organic acid dry cleaning is sequentially performed on another semiconductor wafer W2 inside the chamber 101 with copper Cu deposited therein, the deposited copper Cu may be peeled off and re-deposited on, e.g., the low dielectric constant insulation film 6a exposed on the side surface 7b of the groove 7, as shown in FIG. 9. In this case, as shown in FIG. 10, copper Cu is left below the barrier layer 8 subsequently formed, and is kept diffused into the low dielectric constant insulation film 6a. In the worst case, the low dielectric constant insulation film 6a causes insulation breakdown.

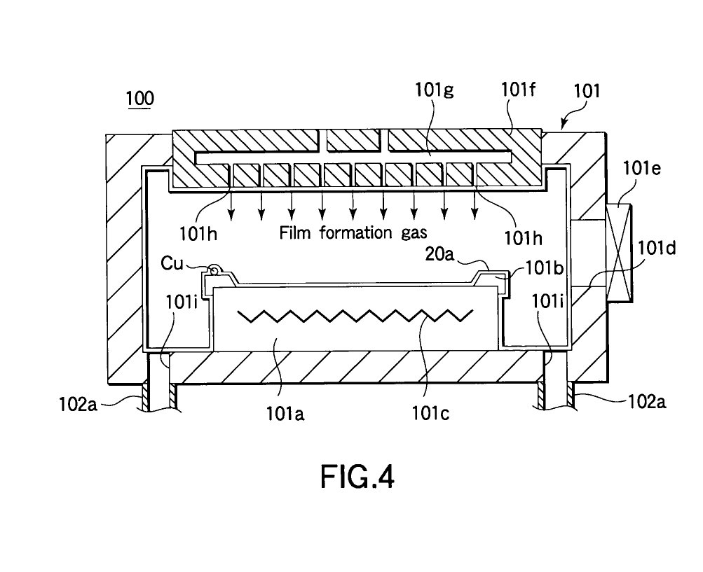

According to this embodiment arranged to solve this problem, as shown in FIG. 4, the first semiconductor wafer W1 processed by the removal of the copper oxide 10 is unloaded from the chamber 101. Then, a film formation gas is supplied into the chamber 101, in which the first semiconductor wafer W1 is no longer present, so that a coating film 20a that cannot be etched by the organic acid dry cleaning is deposited inside the chamber. Consequently, for example, the copper Cu deposited on the guide ring 101b is covered with the coating film 20a. Since the copper Cu is covered with the coating film 20a, it is prevented from being peeled off.

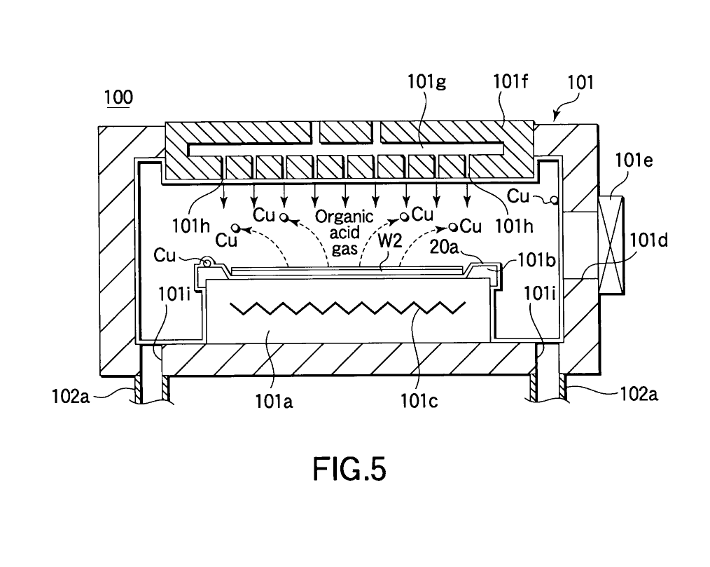

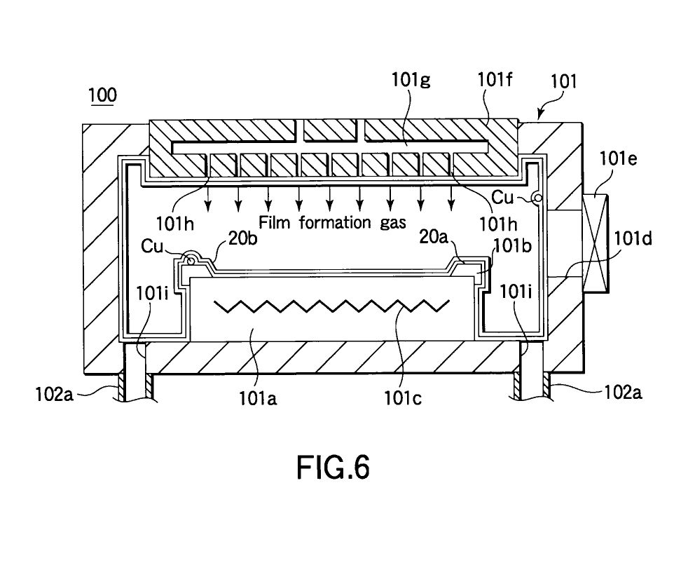

Then, as shown in FIG. 5, the gate valve 101e of the chamber 101 with the coating film 20a deposited therein is opened, and a second semiconductor wafer W2 is loaded into the chamber 101. Thereafter, as in the first semiconductor wafer W1, the organic acid gas is supplied into the chamber 101 to remove copper oxide 10 present on the second semiconductor wafer W2. Also at this time, copper Cu scattered inside the chamber 101 is deposited on, e.g., the inner wall of the chamber, and brings about a new contamination source. Accordingly, as shown in FIG. 6, the second semiconductor wafer W2 is unloaded from the chamber 101, and the film formation gas is supplied into the chamber 101, in which the second semiconductor wafer W2 is no longer present, so that a coating film 20b that cannot be etched by the organic acid dry cleaning is deposited inside the chamber. Consequently, for example, the copper Cu newly deposited on the inner wall of the chamber 101 is covered with the coating film 20b, and is thereby prevented from being peeled off.

As described above, the semiconductor device manufacturing method according to this embodiment is arranged to repeat the organic acid dry cleaning performed on a semiconductor wafer (W1, W2) with copper oxide 10 formed thereon, and the deposition of the coating film (20a, 20b) inside the chamber 101 wherein the coating film cannot be etched by the organic acid dry cleaning. This method makes it possible to prevent copper deposited inside the chamber 101 from being peeled off.

Therefore, according to this embodiment, there is provided a semiconductor device manufacturing method that can perform organic acid dry cleaning without deteriorating interconnection line characteristics.

<Alternative Embodiment>

As the number of repetitions of the organic acid dry cleaning and the deposition of the coating film (20a, 20b) is increased, the number of coating films 20 deposited inside the chamber 101 increases. In order to solve this problem, the following method may be adopted.

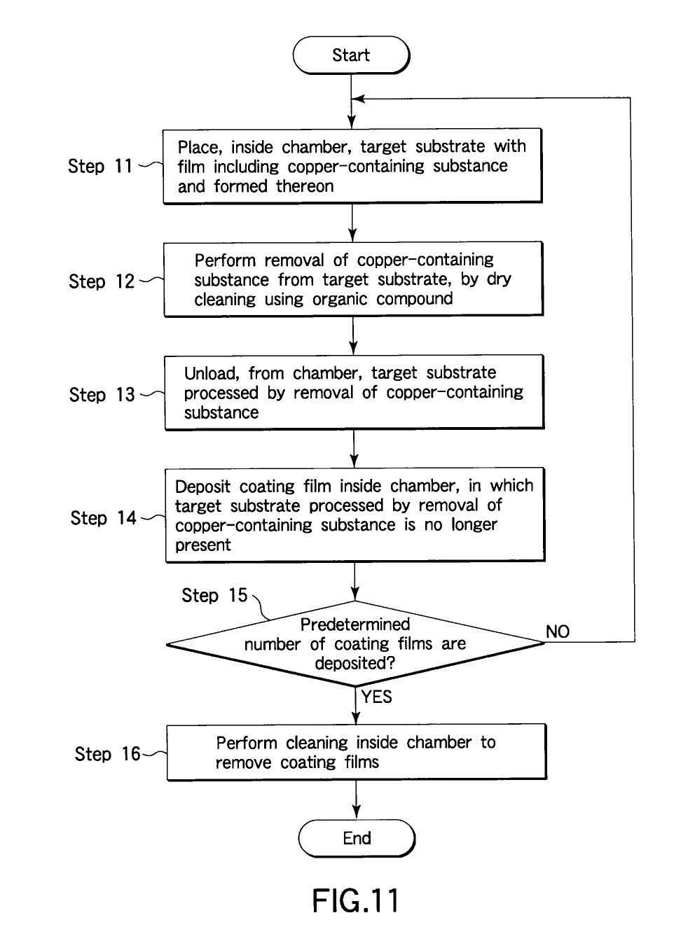

FIG. 11 is a flow chart showing a copper re-deposition preventing method according to an alternative embodiment of the present invention.

In this alternative embodiment, as shown in FIG. 11, the same processes as Step 1 to Step 4 shown in FIG. 1 are first performed in Step 11 to Step 14, respectively. Then, in Step 15, a judgment is made of whether or not the number of coating films thus deposited reaches a predetermined number. If it has not yet reached the predetermined number (NO), the flow returns to Step 11 to perform the processes of the Step 11 to Step 14 again. If it has reached the predetermined number (YES), the flow proceeds to Step 16 to perform cleaning inside the chamber 101, thereby removing the coating films.

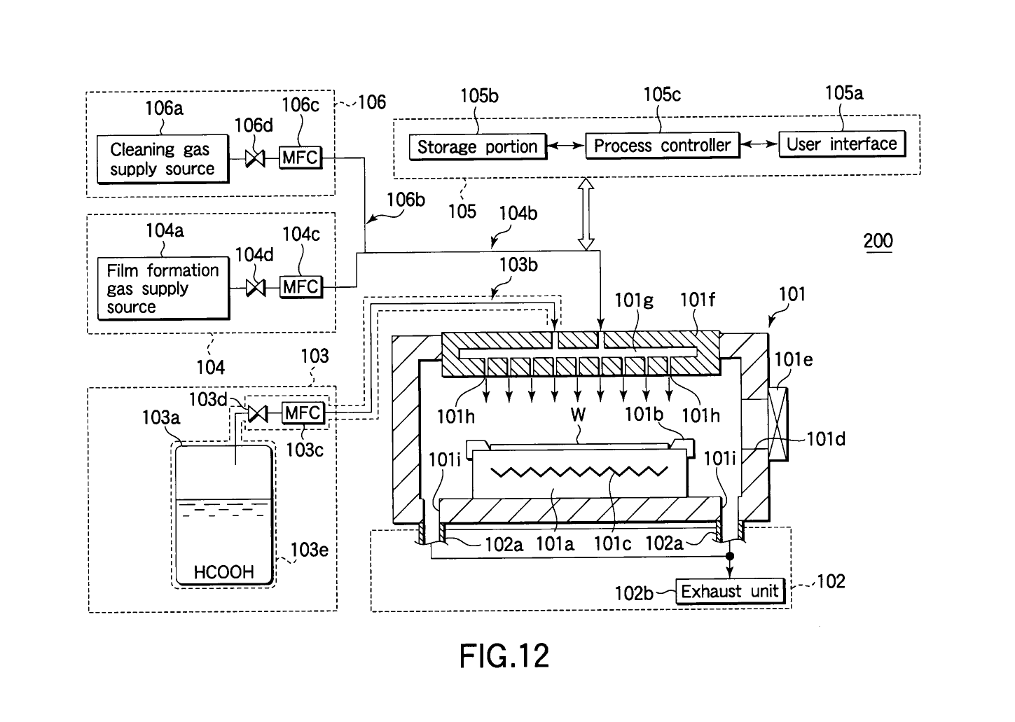

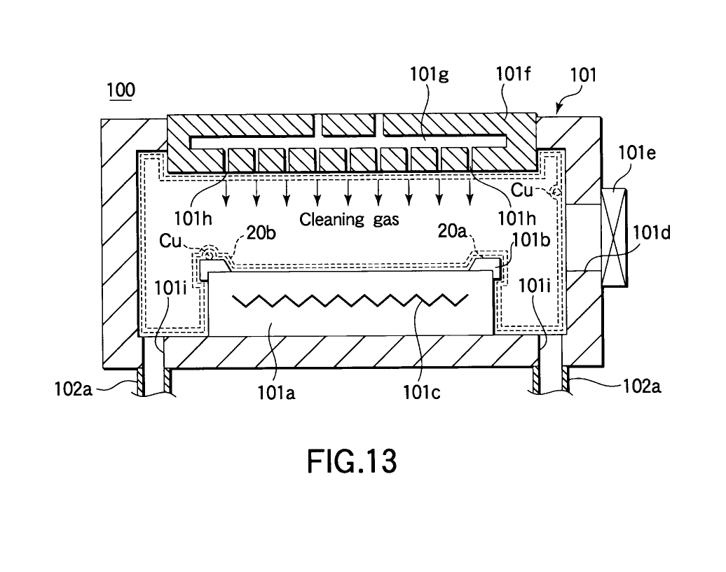

FIG. 12 shows a substrate processing apparatus usable in this alternative embodiment, and FIG. 13 shows a state of the substrate processing apparatus during the cleaning.

As shown in FIG. 12, this organic acid dry cleaning apparatus 200 is the same as the organic acid dry cleaning apparatus 100 shown in FIG. 2, except that a cleaning gas supply mechanism 106 is added to the apparatus 100.

The cleaning gas supply mechanism 106 includes a cleaning gas supply source 106a, and a supply line 106b for supplying a cleaning gas into the diffusion space 101g. The supply line 106b is provided with an MFC 106c and a valve 106d, wherein the MFC 106c is used for adjusting the flow rate of the cleaning gas flowing therethrough.

In this embodiment, the cleaning is supplied from the cleaning gas supply mechanism 106 into the chamber 101, in which no semiconductor wafer is present. Inside the chamber 101, the coating films (20a, 20b) are removed and exhausted along with deposited copper Cu. Consequently, as shown in FIG. 13, the interior of the chamber 101 is brought back into a state where no deposited coating films (20a, 20b) are present, i.e., the initial state.

For example, the flow described above is incorporated in the process recipes and executed by the process controller 105c of the control mechanism 105 shown in FIG. 2, so that, after a predetermined number of coating films 20 (20a, 20b) are deposited, the interior of the chamber 101 is brought back into the initial state where no deposited coating films 20 (20a, 20b) are present. Consequently, the process performed inside the chamber 101 is less fluctuated by an environmental variation due to deposition of coating films 20 (20a, 20b), and so the organic acid dry cleaning can be stably performed.

Further, this alternative embodiment is also advantageous in that deposited copper Cu is removed along with the coating films (20a, 20b) and the effect of removing copper from inside the chamber 101 is thereby enhanced. Particularly, since the coating film 20a is peeled off by the cleaning, copper deposited on the coating film 20a is exhausted along with the coating film 20a out of the chamber 101, and thus is reliably removed. If copper is re-deposited inside the chamber during the cleaning, a new coating film 20 is preferably deposited inside the chamber thereafter.

The cleaning gas can be formed of a well-known gas. For example, where the coating film 20 (20a, 20b) is titanium (Ti), the cleaning gas may be chlorine trifluoride (ClF₃) or the like.

Further, where the coating film 20 is an insulation film, the cleaning gas may be nitrogen trifluoride (NF₃) or the like.

<Examples of Materials>

Next, an explanation will be given of examples of the organic compound, the low dielectric constant insulation film, and the material of the coating film 20 (20a, 20b).

<Organic Compound>

The organic compound may be exemplified by an alcohol having a hydroxyl group (—OH), an aldehyde having an aldehyde group (—CHO), a carboxylic acid including a carboxyl group (—COOH), a carboxylic anhydride, an ester, and a ketone, wherein at least one of these materials may be used.

The alcohol may be exemplified by:

1) a primary alcohol, and particularly a primary alcohol expressed by the following general formula (1),

R¹—OH (1),

(where R¹ is an alkyl group or alkenyl group of a straight chain or branched chain with C₁ to C₂₀, and preferably methyl, ethyl, propyl, butyl, pentyl, or hexyl), which encompasses
methanol (CH₃OH),
ethanol (CH₃CH₂OH),
propanol (CH₃CH₂CH₂OH),
butanol (CH₃CH₂CH₂CH₂OH),
2-methylpropanol ((CH₃)₂CHCH₂OH), and
2-methylbutanol (CH₃CH₂CH(CH₃)CH₂OH);

2) a secondary alcohol, and particularly a secondary alcohol expressed by the following general formula (2),

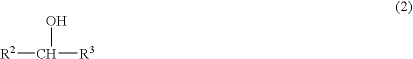

(where each of R² and R³ is an alkyl group or alkenyl group of a straight chain or branched chain with C₁ to C₂₀, and preferably methyl, ethyl, propyl, butyl, pentyl, or hexyl), which encompasses
2-propanol ((CH₃)₂CHOH), and
2-butanol (CH₃CH(OH)CH₂CH₃);

3) a polyhydroxy alcohol, such as diol and triol, which encompasses
ethylene glycol (HOCH₂CH₂OH), and
glycerol (HOCH₂CH(OH)CH₂OH);

4) a cyclic alcohol including 1 to 10, typically 5 to 6, carbon atoms as a part of the ring; and

5) an aromatic alcohol, such as benzyl alcohol (C₆H₅CH₂OH), o-, p-, or m-cresol, or resorcinol.

The aldehyde may be exemplified by:

1) an aldehyde expressed by the following general formula (3),

R⁴—CHO (3)

(where R⁴ is hydrogen, or an alkyl group or alkenyl group of a straight chain or branched chain with C₁ to C₂₀, and preferably methyl, ethyl, propyl, butyl, pentyl, or hexyl), which encompasses
formaldehyde (HCHO),
acetaldehyde (CH₃CHO),
propionaldehyde (CH₃CH₂CHO), and
butylaldehyde (CH₃CH₂CH₂CHO); and

2) an alkanediol compound expressed by the following general formula (4),

OHC—R⁵—CHO (4),

(where R⁵ is a saturated or unsaturated hydrocarbon of a straight chain or branched chain with C₁ to C₂₀, but such a modification may be acceptable that R⁵ is excluded and the two aldehyde groups are bonded to each other).

The carboxylic acid may be exemplified by a carboxylic acid expressed by the following general formula (5),

R⁶—COOH (5),

(where R⁶ is hydrogen, or an alkyl group or alkenyl group of a straight chain or branched chain with C₁ to C₂₀, and preferably methyl, ethyl, propyl, butyl, pentyl, or hexyl).

For example, this type includes:
formic acid (HCOOH),
acetic acid (CH₃COOH),
propionic acid (CH₃CH₂COOH),
butyric acid (CH₃(CH₂)₂COOH), and
valeric acid (CH₃(CH₂)₃COOH).

Further, the carboxylic acid may be exemplified by a polycarboxylic acid or carboxylic halide.

The carboxylic anhydride may be a substance expressed by the following general formula (6),

R⁷—CO—O—CO—R⁸ (6),

(where each of R⁷ and R⁸ is hydrogen atom or a hydrocarbon group, or a functional group in which hydrogen atoms forming a hydrocarbon group are at least partly replaced with halogen atoms).

The hydrocarbon group may be exemplified by an alkyl group, an alkenyl group, an alkynyl group, and an allyl group. The halogen atom may be exemplified by fluorine, chlorine, bromine, and iodine.

The carboxylic anhydride may be exemplified by formic anhydride, propionic anhydride, acetic/formic anhydride, butyric anhydride, and valeric anhydride, as well as acetic anhydride described above.

The ester may be a substance expressed by the following general formula (7),

R⁹—COO—R¹⁰ (7),

(where R⁹ is hydrogen atom or a hydrocarbon group, or a functional group in which hydrogen atoms forming a hydrocarbon group are at least partly replaced with halogen atoms, and R¹⁰ is a hydrocarbon group or a functional group in which hydrogen atoms forming a hydrocarbon group are at least partly replaced with halogen atoms).

The hydrocarbon group and halogen atom may be exemplified by the same substances as those described above.

The ester may be exemplified by methyl formate, ethyl formate, propyl formate, butyl formate, benzyl formate, methyl acetate, ethyl acetate, propyl acetate, butyl acetate, pentyl acetate, hexyl acetate, octyl acetate, phenyl acetate, benzyl acetate, allyl acetate, propenyl acetate, methyl propionate, ethyl propionate, butyl propionate, pentyl propionate, benzyl propionate, methyl butyrate, ethyl butyrate, pentyl butyrate, butyl butyrate, methyl valerate, and ethyl valerate.

<Low Dielectric Constant Insulation Film>

In the embodiments described above, a material that allows copper to be easily diffused can be used for an interlayer insulation film, because copper re-deposition is prevented. Accordingly, each of the interlayer insulation films 2 and 6 is preferably formed of a low dielectric constant insulation film (Low-k film) having a dielectric constant lower than those of inorganic silicon oxide films. The low dielectric constant insulation film means an insulation film that has a dielectric constant lower than those of inorganic silicon oxide films. For example, inorganic silicon oxide films deposited by a CVD method using TEOS as a source gas have a dielectric constant k of about 4.2. Accordingly, in this specification, the low dielectric constant insulation film is defined as an insulation film having a dielectric constant k of less than 4.2.

The low dielectric constant insulation films 2 and 6 may be formed of a material exemplified by:

1) a siloxane-family material,

2) an organic material, and

3) a porous material.

The siloxane-family material may be exemplified by:

1) a material containing Si, O, and H, such as HSQ (Hydrogen-Silsesquioxane), and

2) a material containing Si, C, O, and H, such as MSQ (Methyl-Silsesquioxane).

The organic material may be exemplified by:

1) a polyallylene ether-family material,

2) a polyallylene hydrocarbon-family material,

3) a parylene-family material,

4) a benzocyclobutene (BCB)-family material,

5) a polytetrafluoroethylene (PTFE)-family material,

6) a polyimide fluoride-family material, and

7) a CF-family material prepared by use of a fluorocarbon gas as a source.

The porous material may be exemplified by:

1) porous MSQ,

2) porous polyallylene hydrocarbon, and

3) porous silica.

Further, where the interlayer insulation films 2 and 6 comprise low dielectric constant insulation films, the hard mask layers 2b and 6b and etching stopper layer 6c may be additionally used.

The hard mask layers 2b and 6b may be formed of a material exemplified by:

1) polybenzooxazole,

2) SiOC, and

3) SiC.

The etching stopper layer 6c may be formed of the same material as the hard mask layers 2b and 6b.

<Coating Film>

The material of the coating film may be exemplified by metal materials, such as Ta, Ti, W, Mn, Ru, Zn, and Al, oxide of these metal materials, nitride of these metal materials, carbide of these metal materials, and silicide of these metal materials, and further by SiO, SiN, SiOC, SiC, SiCN, and SiOCN.

Next, an explanation will be given of examples of the film formation gas for forming the coating film.

Where a Ta film is formed as the coating film, a metal compound used as a source material may be exemplified by:

tantalum pentachloride (TaCl₅),

tantalum pentafluoride (TaF₅),

tantalum pentabromide (TaBr₅),

tantalum pentaiodide (TaI₅),

tertiarybutylimidotris(diethylamido)tantalum (Ta(NC(CH₃)₃)(N(C₂H₅)₂)₃ (TBTDET)), and

tertiaryamylimidotris(dimethylamido)tantalum (Ta(NC(CH₃)₂C₂H₅)(N(CH₃)₂)₃).

Where a Ti film is formed as the coating film, a metal compound used as a source material may be exemplified by:

titanium tetrachloride(TiCl₄),

titanium tetrafluoride (TiF₄),

titanium tetrabromide (TiBr₄),

titanium tetraiodide (TiI₄),

tetrakisethylmethylamino titanium (Ti[N(C₂H₅CH₃)]₄ (TEMAT)),

tetrakisdimethylamino titanium (Ti[N(CH₃)₂]₄ (TDMAT)), and

tetrakisdiethylamino titanium (Ti[N(C₂H₅)₂]₄ (TDEAT)).

Where a W film is formed as the coating film, a metal compound used as a source material may be exemplified by:

tungsten hexafluoride (WF₆), and

tungsten carbonyl (W(CO)₆).

Where an Mn film is formed as the coating film, a metal compound used as a source material may be exemplified by:

bis(cyclopentadienyl)manganese(Mn(C₅H₅)₂),

bis(methylcyclopentadienyl)manganese (Mn(CH₃C₅H₄)₂),

bis(ethylcyclopentadienyl)manganese (Mn(C₂H₅C₅H₄)₂),

bis(propylcyclopentadienyl)manganese (Mn(C₃H₇C₅H₄)₂),

bis(t-butylcyclopentadienyl)manganese (Mn(C₄H₉C₅H₄)₂),

bis(acetylacetonate)manganese (Mn(C₅H₇O₂)₂),

bis(pentamethylcyclopentadienyl)manganese (II) (Mn(C₅(CH₃)₅)₂),

bis(tetramethylcyclopentadienyl)manganese (II) (Mn(C₅(CH₃)₄H)₂) (DMPD),

(ethylcyclopentadienyl)manganese (Mn(C₇H₁₁C₂H₅C₅H₄)),

tris(DPM) manganese (Mn(C₁₁H₁₉O₂)₃),

manganese (0) carbonyl (Mn₂(CO)₁₀),

methyl manganese pentacarbonyl (CH₃Mn(CO)₅),

cyclopentadienyl manganese (I) tricarbonyl ((C₅H₅)Mn(CO)₃),

methylcyclopentadienyl manganese (I) tricarbonyl ((CH₃C₅H₄)Mn(CO)₃),

ethylcyclopentadienyl manganese (I) tricarbonyl ((C₂H₅C₅H₄)Mn(CO)₃),

acetylcyclopentadienyl manganese (I) tricarbonyl ((CH₃COC₅H₄)Mn(CO)₃), and

hydroxy isopropylcyclopentadienyl manganese (I)tricarbonyl ((CH₃)₂C(OH)C₅H₄)Mn(CO)₃).

Where an Ru film is formed as the coating film, a metal compound used as a source material may be exemplified by:

bis(cyclopentadienyl)ruthenium,

tris(2,2,6,6-tetramethyl-3,5-heptanedionato)ruthenium,

tris(N,N′-diisopropylacetoamidinate)ruthenium (III),

bis(N,N′-diisopropylacetoamidinate)ruthenium (II) dicarbonyl,

bis(ethylcyclopentadienyl)ruthenium,

bis(pentamethylcyclopentadienyl)ruthenium,

bis(2,2,6,6-tetramethyl-3,5-heptanedionato)(1,5-cyclooctadiene)ruthenium (II), and

ruthenium (III) acetylacetonate.

Where a Zn film is formed as the coating film, a metal compound used as a source material may be exemplified by:

ZnF₂, ZnCl₂, ZnBr₂, ZnI₂, and Zn(C₂H₅)₂.

Where an Al film is formed as the coating film, a metal compound used as a source material may be exemplified by:

AlCl₃, Al(CH₃)₂H, and Al(CH₃)₃.

Where a metal oxide film of one of the metals (Ta, Ti, W, Mn, Ru, Zn, and Al) described above is formed as the coating film, a metal compound, such as one of those described above, used as a source material may be combined with one of:

O₂, O₃, and N₂O.

Where a metal nitride film of one of the metals (Ta, Ti, W, Mn, Ru, Zn, and Al) described above is formed as the coating film, a metal compound, such as one of those described above, used as a source material may be combined with one of:

N₂ and NH₃.

Where a metal carbide film of one of the metals (Ta, Ti, W, Mn, Ru, Zn, and Al) described above is formed as the coating film, a metal compound, such as one of those described above, used as a source material may be combined with one of:

CH₄, C₂H₂, C₂H₄, C₂H₆, and C₃H₈.

Where a metal silicide film of one of the metals (Ta, Ti, W, Mn, Ru, Zn, and Al) described above is formed as the coating film, a metal compound, such as one of those described above, used as a source material may be combined with one of:

SiH₄ and Si₂H₆.

Where an SiO film is formed as the coating film, an Si source material exemplified by:

SiH₄,

Si₂H₆, and

TEOS (Si(OC₂H₅)₄),

may be combined with one of:

O₂, O₃, and N₂O.

Where an SiN film is formed as the coating film, an Si source material exemplified by:

SiH₄, and

BTBAS (Si[N(C₂H₅)₂]₂H₂),

may be combined with one of:

N₂ and NH₃.

Where an SiOC film is formed as the coating film, an SiC source material exemplified by:

Si(CH₃)₃H,

Si(CH₃)₄,

HMDSO ((CH₃)₃Si—O—Si(CH₃)₃),

DMDMOS (Si(CH₃)₂(OCH₃)₂),

TMCTS ([SiH(CH₃)O]₄), and

OMCTS ([Si(CH₃)₂O]₄),

may be combined with one of:

O₂, O₃, and N₂O,

wherein the DMDMOS, TMCTS, and OMCTS do not necessarily require O₂, O₃, or N₂O to be combined therewith.

Where an SiC film is formed as the coating film, a source material may be exemplified by:

Si(CH₃)₃H, and

Si(CH₃)₄.

Where an SiCN film is formed as the coating film, an SiC source material exemplified by:

Si(CH₃)₃H,

Si(CH₃)₄, and

HMDS ((CH₃)₃Si—NH—Si(CH₃)₃),

may be combined with one of:

N₂ and NH₃,

wherein the HMDS does not necessarily require N₂ or NH₃ to be combined therewith.

Where an SiOCN film is formed as the coating film, an SiOC film formation gas, such as one of those described above, may be combined with one of:

N₂ and NH₃.

In order to form the film described above, a well-known film formation method may be used. In the embodiments described above, thermal CVD is used, but plasma CVD may be used. In this case, the chamber shown in FIG. 2 may be simply provided with a plasma generation mechanism. The plasma generation mechanism may be exemplified by:

(1) a system comprising a radio frequency power supply, a radio frequency cable, and a radio frequency matching unit; and

(2) a system comprising a microwave power supply, a waveguide tube, and a microwave matching unit.

In the embodiments described above, the coating film is conceived to cover and seal copper deposited inside the chamber 101. Accordingly, formation of the coating film does not require strict process control, such as strict temperature control, unlike film formation on semiconductor wafers. The temperature used for formation of the coating film may be set to be the same as the substrate temperature used for the other processes, such as the organic acid dry cleaning, so as to simplify the temperature control and to shorten the process time.

According to the embodiments of the present invention described above, there is provided a copper re-deposition preventing method, which can prevent copper from being re-deposited on a target substrate, and a semiconductor device manufacturing method utilizing this preventing method, which can perform organic acid dry cleaning without deteriorating interconnection line characteristics. Further, there is provided a substrate processing apparatus usable for performing the preventing method, and a storage medium for controlling the substrate processing apparatus.

The present invention has been described with reference to embodiments, but the present invention is not limited to the embodiments described above, and it may be modified in various manners within the scope of the claims. In place of the embodiments described above, the present invention may be realized in other embodiments.

For example, in the embodiments described above, a copper re-deposition preventing method is applied to a process for removing the copper oxide 10 from the copper interconnection line 4. In place of a process for removing the copper oxide 10 from the copper interconnection line 4, a copper re-deposition preventing method may be applied to a process for removing copper oxide from an internal electric connector member. Alternatively, a copper re-deposition preventing method may be applied to a process for removing copper oxide after CMP.

Further, in the embodiments described above, an organic acid dry cleaning apparatus is shown as a substrate processing apparatus usable for performing a copper re-deposition preventing method. In place of an apparatus having only an organic acid dry cleaning function, the present invention may be applied to another substrate processing apparatus including an organic acid dry cleaning function, such as a photo-resist ashing apparatus including an organic acid dry cleaning function.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A copper re-deposition preventing method comprising:
placing inside a chamber a target substrate with a film including a copper-containing substance and formed thereon;
performing removal of the copper-containing substance from the target substrate placed inside the chamber, by dry cleaning using an organic compound;
unloading from the chamber the target substrate processed by the removal of the copper-containing substance; and
depositing a coating film inside the chamber, in which the target substrate processed by the removal of the copper-containing substance is no longer present, thereby covering copper-containing scattered particles left inside the chamber.

2. The copper re-deposition preventing method according to claim 1, wherein the copper-containing substance is copper oxide.

3. The copper re-deposition preventing method according to claim 1, wherein the organic compound is selected from the group consisting of an alcohol, an aldehyde, a carboxylic acid, a carboxylic anhydride, an ester, and a ketone.

4. The copper re-deposition preventing method according to claim 3, wherein the organic compound is an alcohol selected from the group consisting of a primary alcohol, a secondary alcohol, a polyhydroxy alcohol, a cyclic alcohol including a plurality of carbon atoms as a part of its ring, and an aromatic alcohol.

5. The copper re-deposition preventing method according to claim 3, wherein the organic compound is an aldehyde selected from the group consisting of:
an aldehyde expressed by a formula (1),
R¹—CHO (1)
(where R¹ is hydrogen, or an alkyl group or alkenyl group of a straight chain or branched chain with C₁ to C₂₀);
an alkanediol compound expressed by a formula (2),
OHC—R²—CHO (2),
(where R² is a saturated or unsaturated hydrocarbon of a straight chain or branched chain with C₁ to C₂₀); and
a substance prepared such that R² is excluded and two aldehyde groups are bonded to each other in an alkanediol compound expressed by the formula (2).

6. The copper re-deposition preventing method according to claim 3, wherein the organic compound is a carboxylic acid selected from the group consisting of:
a carboxylic acid expressed by a formula (3),
R³—COOH (3),
(where R³ is hydrogen, or an alkyl group or alkenyl group of a straight chain or branched chain with C₁ to C₂₀);
a polycarboxylic acid; and
a carboxylic halide.

7. The copper re-deposition preventing method according to claim 3, wherein the organic compound is a carboxylic anhydride selected from a carboxylic anhydride expressed by a formula (4),
R⁴—CO—O—CO—R⁵ (4),
(where each of R⁴ and R⁵ is hydrogen atom or a hydrocarbon group, or a functional group in which hydrogen atoms forming a hydrocarbon group are at least partly replaced with halogen atoms).

8. The copper re-deposition preventing method according to claim 3, wherein the organic compound is an ester selected from an ester expressed by a formula (5),
R⁶—COO—R⁷ (5)
(where R⁶ is hydrogen atom or a hydrocarbon group, or a functional group in which hydrogen atoms forming a hydrocarbon group are at least partly replaced with halogen atoms, and R⁷ is a hydrocarbon group or a functional group in which hydrogen atoms forming a hydrocarbon group are at least partly replaced with halogen atoms).

9. The copper re-deposition preventing method according to claim 1, wherein the coating film is made of a material selected from the group consisting of metal materials, Ta, Ti, W, Mn, Ru, Zn, and Al, oxide of these metal materials, nitride of these metal materials, carbide of these metal materials, and silicide of these metal materials, and SiO, SiN, SiOC, SiC, SiCN, and SiOCN.

10. The copper re-deposition preventing method according to claim 1, wherein the method further comprises cleaning an interior of the chamber to remove layers each comprising the coating film deposited inside the chamber, after repeating said depositing a coating film a predetermined number of times.

11. A semiconductor device manufacturing method comprising:
placing inside a chamber a first semiconductor substrate with a film including a copper-containing substance and formed thereon;
performing removal of the copper-containing substance from the first semiconductor substrate placed inside the chamber, by dry cleaning using an organic compound;
unloading from the chamber the first semiconductor substrate processed by the removal of the copper-containing substance;
depositing a first coating film inside the chamber, in which the first semiconductor substrate processed by the removal of the copper-containing substance is no longer present, thereby covering copper-containing scattered particles left inside the chamber;
placing, inside a chamber with the first coating film deposited therein, a second semiconductor substrate with a film including a copper-containing substance and formed thereon;
performing removal of the copper-containing substance from the second semiconductor substrate placed inside the chamber with the first coating film deposited therein, by the dry cleaning using an organic compound;
unloading, from the chamber with the first coating film deposited therein, the second semiconductor substrate processed by the removal of the copper-containing substance; and
depositing a second coating film inside the chamber with the first coating film deposited therein, in which the second semiconductor substrate processed by the removal of the copper-containing substance is no longer present, thereby covering copper-containing scattered particles left inside the chamber.

12. The semiconductor device manufacturing method according to claim 11, wherein the dry cleaning using an organic compound, said depositing a first coating film, and said depositing a second coating film are preset to use the same process temperature.

13. A substrate processing apparatus comprising:
a chamber;
an organic compound-containing gas supply mechanism configured to supply an organic compound-containing gas into the chamber;
a film formation gas supply mechanism configured to supply a film formation gas for forming a coating film into the chamber; and
a process controller configured to control an operation of the apparatus,
wherein the process controller is preset to execute
supplying the organic compound-containing gas into the chamber, in which a target substrate with a film including a copper-containing substance and formed thereon is placed, thereby performing removal of the copper-containing substance from the target substrate, by dry cleaning using the organic compound, and,
subsequently to unloading from the chamber the target substrate processed by the removal of the copper-containing substance,
supplying the film formation gas into the chamber, in which the target substrate processed by the removal of the copper-containing substance is no longer present, thereby depositing a coating film inside the chamber and covering copper-containing scattered particles left inside the chamber.

14. The substrate processing apparatus according to claim 13, wherein the process controller is preset to execute cleaning an interior of the chamber to remove layers each comprising the coating film deposited inside the chamber, after repeating said depositing a coating film a predetermined number of times.

15. A storage medium that stores a program for execution on a computer for controlling a substrate processing apparatus, wherein the program, when executed, causes the computer to control the substrate processing apparatus to conduct a copper re-deposition preventing method comprising:
placing inside a chamber a target substrate with a film including a copper-containing substance and formed thereon;
performing removal of the copper-containing substance from the target substrate placed inside the chamber, by dry cleaning using an organic compound;
unloading from the chamber the target substrate processed by the removal of the copper-containing substance; and
depositing a coating film inside the chamber, in which the target substrate processed by the removal of the copper-containing substance is no longer present, thereby covering copper-containing scattered particles left inside the chamber.
